(19) United States
(12) Patent Application Publication
(10) Pub. No.: US 2010/0176852 A1
(43) Pub. Date: Jul. 15, 2010

(54) SPREAD SPECTRUM CLOCK GENERATOR USING ARRIVAL LOCKED LOOP TECHNOLOGY

(76) Inventor: Wen T. Lin, Ambler, PA (US)

Correspondence Address: FOX ROTHSCHILD LLP;PRINCETON PIKE CORPORATE CENTER, 997 LENOX DRIVE, BLDG. #3, LAWRENCEVILLE, NJ, 08648, US

(21) Appl. No.: 12/443,553

(22) PCT Filed: Sep. 28, 2007
(86) PCT No.: PCT/US07/79898

§ 371 Date: Mar. 11, 2010

Related U.S. Application Data
(60) Provisional application No. 60/827,288, filed on Sep. 28, 2006.

(51) Int. Cl. H03L 7/06

(52) U.S. Cl. 327/155

(57) ABSTRACT

A new technique using arrival locked loop technology to produce a spread spectrum clock signal with random frequency modulation and with precise variable frequency spread is presented. The arrival locked loop includes three modules, the arrival comparator with a precise spread control, the loop filter and the VCO. An arrival locked loop is made unstable and oscillates at a certain frequency to produce a low frequency modulation signal on the final error correction output to spread the high frequency output signal from VCO in frequency. The period of frequency spread in each cycle of the low frequency modulation signal also increases by a small random amount of time cycle after cycle until the period of frequency spread becomes so long that cycle-slip is produced to the punctual signal at the input of arrival comparator to reset the period of frequency spread to a small amount.

### CROSS REFERENCE TO APPLICATIONS

This application is related to, and claims priority to U.S. Provisional Application No. 60/827,288, filed on Sep. 28, 2006, and is also related to PCT Application No. PCT/US05/26842, filed on Jul. 28, 2005, and to PCT Application No. PCT/US06/17856, filed on May 4, 2006, and also to PCT Application No. PCT/US06/060599, filed on Nov. 6, 2006, the entire contents of all of which are hereby incorporated by reference.

### BACKGROUND OF THE INVENTION

The present invention relates to the field of digital signal processing, and more specifically, the present invention relates to methods, apparatus, and systems for improved spread spectrum clock generation.

### BACKGROUND ART

The spread spectrum clock technology has become very popular among electronic products, especially the PCs, in the past decade. This technology can effectively reduce the peak strength of spurious radiations from the clock signal and its harmonics of the PC so that the PC can be built with less RF shielding; in other words, less cost, weight and time and still passes the electromagnetic field interference (EMI) requirements set by the FCC for electronic products. The principle of this technology is to spread the frequency of the clock signal evenly into a bandwidth of small percentage of the clock frequency so that the radiated clock signal energy will not stay at one fixed frequency all the time. As a result, the peak strength of spurious radiations from the clock signal at the clock frequency and its harmonics is spread out and its power density is greatly reduced.

The amount of reduction in the power density of peak spurious radiations is determined by how the clock signal is spread in frequency. The most common method to spread the frequency of clock signal is to use a triangular frequency modulation signal with a linear ramp up and ramp down slope to evenly spread the frequency of the clock signal over a small percentage of the clock frequency. The typical response of clock spreading with a triangular frequency modulation signal is as shown in FIG. 1. The frequency spreading can effectively reduce the peak strength of the clock signal radiations by the spreading loss 102 which is typically only 8 to 14 db with the current technology. Unfortunately, spread by a triangular frequency modulation, the energy spectrum of the clock signal always inevitably peaks up at both ends of the clock spectrum because the clock signal spends more time staying at both ends of the frequency spreading. Many techniques were developed during the past decade to improve the spreading waveform so that the clock energy will spread out more evenly but all these current methods can only do so much because all the spreading functions used today are deterministic. Since a deterministic signal repeats itself at a certain rate, a repetitive deterministic modulation signal will allow the quasi-peak detector to pump up the detector's output to be eventually equal to the peak power of the clock signal. The repetitiveness of the deterministic modulation signal thus significantly limits the amount of spreading loss 102 that can be possibly produced since the spreading loss 102 is limited to the ratio of spread bandwidth to the fixed measurement bandwidth set by FCC.

If the clock signal is spread by a random noise modulation signal instead; since a random noise never repeats itself, the quasi-peak detector will not be able to pump the detector's output up regularly to reach the peak power of the clock signal any more. As a result, when the power density of the clock signal modulated with random noise is measured by the quasi-peak detector, the measured power density is always equal to the averaged power of the clock signal instead of peak power. Since the ratio of peak power to averaged power of a random noise signal can be very large, depending upon how random the random noise signal is, a random noise modulation signal can significantly reduce the power density of the clock signal and produce a much larger spreading loss 161 that is much larger than the ratio of spread bandwidth to the fixed measurement bandwidth as shown also in FIG. 1. Unfortunately, it has been very difficult to implement a spread spectrum clock system inside an IC with a random noise modulation signal with the current technology.

Currently, there are many ways to spread the clock signal; the simplest way is to dither the programmable divider of a PLL to modulate the frequency of clock signal and the most complicated way is to use a look-up table to store the spreading function for the modulation of clock signal. Both methods produce a smooth deterministic frequency modulation signal to spread the frequency of VCO. The U.S. Pat. No. 5,610,955 represents the first method while the U.S. Pat. No. 6,377,646B1 represents the second approach. As explained earlier, these methods produce a smooth deterministic function to modulate the VCO in frequency so that the energy level of the spurious clock radiation signals is still very concentrated. U.S. Pat. No. 5,506,545 provides an analog solution to produce a random frequency modulation signal by using a noise source to spread the frequency of VCO. This solution provides a true random noise to spread the frequency of clock signal; however, it is very difficult to implement this analog design inside an integrated circuit.

The inventions presented in PCT application PCT/US06/060599 “Nonlinear feedback control loop as spread spectrum clock generator” could finally produce a random noise modulation signal to spread the frequency of clock signal by harnessing the intrinsic noise around a nonlinear feedback control loop so that a spread spectrum clock generator with random noise modulation can be built inside an IC easily. There are four possible ways to build the nonlinear feedback control loop by either comparing the frequencies or phases or amplitudes or arrivals of the signals and the more favorable nonlinear feedback control loops to produce a spread spectrum clock signal are the loops that use a VCO as the feedback module, such as the frequency locked loop and arrival locked loop, since the VCO is capable of producing a large frequency spread. Between the two methods that use VCO as the feedback module, the arrival locked loop is the preferred method to produce the spread spectrum clock because the frequency locked loop has more latency delay and the modulation frequency of the clock signal generated from a frequency locked loop is always lower than the modulation frequency of clock signal generated from an arrival locked loop. Since the modulation frequency of the clock is required to be higher than 30 Khz to be way above the audible frequency range, the arrival locked loop is the better solution to satisfy this requirement. However, since the principle of producing a random frequency spread from a nonlinear feedback control loop is to increase the period of frequency spread cycle after cycle by a small random amount of time for every cycle of the frequency spread until the period of frequency spread becomes so long that cycle-slip occurs to reset the period of frequency spread. Cycle-slip is the reason that the frequency spread of the feedback signal from VCO becomes randomized Since the feedback signal of an arrival locked loop needs to travel a whole cycle of comparison clock signal to produce a cycle-slip, it was very difficult to produce a spread spectrum clock signal with a small frequency spread from the arrival locked loop technology. A new technique presented in this disclosure finally solves this problem by limiting the range of traveling for the feedback signal to produce cycle-slips so that an arrival locked loop can now produce a spread spectrum clock signal with a small random frequency spread easily.

It is also known from the PCT application PCT/US2006/060599 “Nonlinear feedback control loop as spread spectrum clock generator” that the polarity of the error comparator can be reversed when the nonlinear feedback control loop is oscillating since the error comparator produces both correct and incorrect decisions for equally half of the time in the oscillation phase. From this concept, a toggle switch 600 controlled by a random signal generator 602 can be used to flip the polarity of the error comparator 118 randomly to randomize the frequency spread of spread spectrum clock signal even more. Although the random polarity switching is an effective technique to improve the randomness of frequency spread, it requires an additional random signal generator 602 and a large amount of hardware is needed to implement the random signal generator 602. A new method to produce a random signal to control the polarity reversal switch 600 with much less hardware than needed for a random signal generator 602 is presented in this patent disclosure.

### SUMMARY OF THE INVENTION

A new technique using arrival locked loop technology 154 to produce a spread spectrum clock signal with random frequency modulation and with precise variable frequency spread is presented in this disclosure. The arrival locked loop 154 includes three modules, the arrival comparator (330, 340, 360) with a precise spread control, the loop filter 106 and the VCO 108. The principle of this technique is to make an arrival locked loop 154 unstable and oscillating at a certain frequency to produce a low frequency modulation signal on the final error correction output 115 to spread the high frequency output signal 332 from VCO 108 in frequency; the period of frequency spread in each cycle of the low frequency modulation signal also increases by a small random amount of time cycle after cycle until the period of frequency spread becomes so long that cycle-slip is produced to the punctual signal 328 at the input of arrival comparator 191 to reset the period of frequency spread to a small amount. The process to grow and to reset the period of frequency spread repeats forever so that the low frequency modulation signal on the final error correction output 115 becomes completely random in phase, frequency and amplitude for every cycle of the frequency spread to produce the ideal random frequency spread for the spread spectrum clock signal 332.

Three arrival comparators 191 are needed to implement this technique, a punctual arrival comparator, a late arrival comparator and an early arrival comparator; and the nonlinear arrival locked loop 154 uses the punctual arrival comparator to generate the spread spectrum clock output signal modulated with a random low frequency modulation signal and also uses the early arrival comparator and the late arrival comparator to generate the cycle-slips to limit the frequency spread of the spread spectrum clock output signal generated from the punctual arrival comparator. With the early arrival comparator and the late arrival comparator to produce cycle-slips, the frequency spread of spread spectrum clock signal is precisely controlled and the amount of peak-to-peak frequency spread can be changed easily by adjusting the arrival-time difference between the punctual signal 328 and the early signal 326 and between the punctual signal 328 and the late signal 316. Since the spread spectrum clock output signal produced from the arrival locked loop 154 does not need to travel far to produce cycle-slips, a small, variable and precise frequency spread on the spread spectrum clock output signal 332 is produced.

Since the cycle-slip always occurs randomly when the frequency of the spread spectrum clock signal produced by an arrival locked loop 154 is approaching the center frequency of the clock, the cycle-slip signals 404 can be used to toggle the polarity of output signal from the arrival comparator 191 to randomize the frequency spread even more. As a result, using the cycle-slip signals 404 as the random signal to toggle the polarity of the output signal from the arrival comparator can save a significant amount of hardware for random signal generator 602.

Although the technique using arrival comparator (330, 340) with precise spread control for the arrival locked loop 154 can produce a spread spectrum clock signal with small and random frequency spread, the arrival locked loop 154 can be trapped due to the cycle-slip. Two watchdogs 394 are thus needed for the arrival comparator 360 with precise spread control to totally prevent the loop 154 from being trapped.

This and other features of the present inventions will now be described in detail by referencing to the following figures.

### BRIEF DESCRIPTION OF THE DRAWINGS

FIG. 1 The spectrum of clock signal modulated with a triangular signal and with a random signal. (prior art).

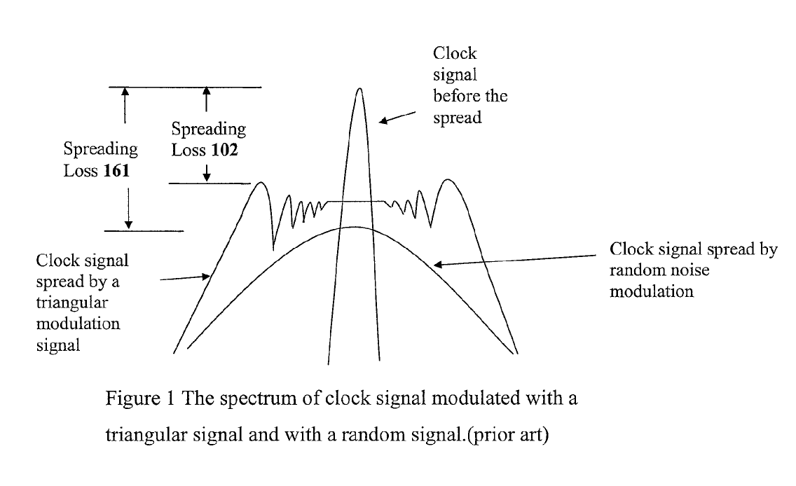

FIG. 2 The block diagram for a spread spectrum clock generator using a basic nonlinear feedback control loop.

FIG. 3 The block diagram for a spread spectrum clock generator using a basic arrival locked loop.

FIG. 4 The block diagram for a spread spectrum clock generator using the nonlinear arrival locked loop with precise spread control.

FIG. 5 The acquisition behavior of the digital arrival locked loop.

FIG. 6 The crossing of arrival threshold.

FIG. 7 The schematics for an accurate nonlinear arrival comparator with a single-ended decision output.

FIG. 8 The schematics for an accurate nonlinear arrival comparator with a double-ended pump and sink output.

FIG. 9 The schematics for an accurate nonlinear arrival comparator with a double-ended pump and sink output and with a CLEAR input.

FIG. 10 The block diagram for an accurate arrival comparator with a precise spread control and a single-ended output as the preferred embodiment.

FIG. 11 The generation of cycle-slip signals and the timing diagram of feedback signals.

FIG. 12 The block diagram for an accurate arrival comparator with precise spread control and a polarity reversal toggle switch as an alternate embodiment.

FIG. 13 The block diagram for a spread spectrum clock generator using a nonlinear feedback control loop with random polarity reversal.

FIG. 14 The acquisition behavior of arrival locked loop with polarity reversal.

FIG. 15 The block diagram for the state machine of polarity reversal.

FIG. 16 The schematics for using cycle-slip signals as the random signal generator to produce the random reversal signal.

FIG. 17 The block diagram for an accurate arrival comparator with precise spread control and random polarity reversal and watchdog as another alternate embodiment.

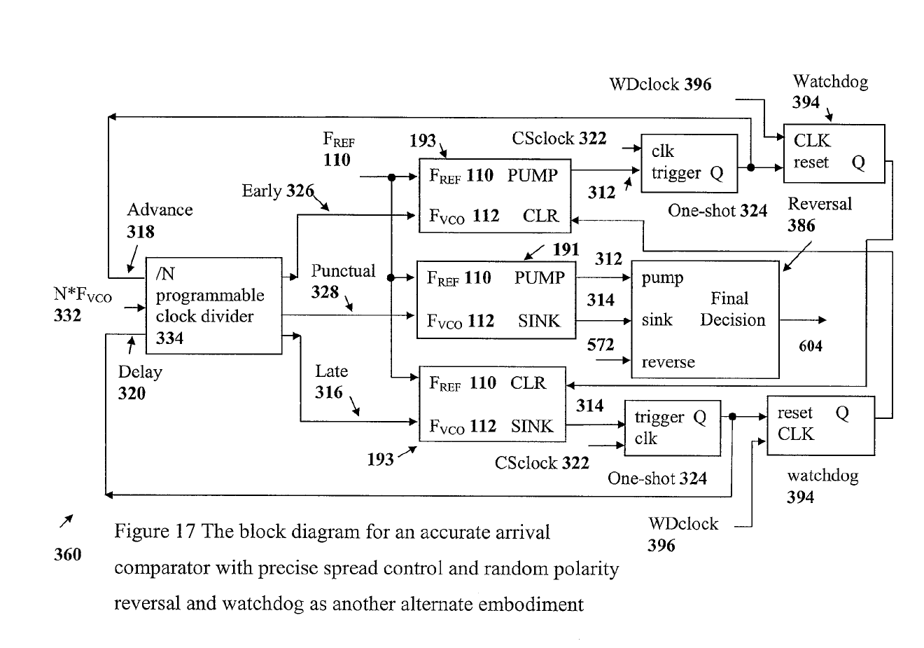

### DETAILED DESCRIPTION OF THE INVENTION

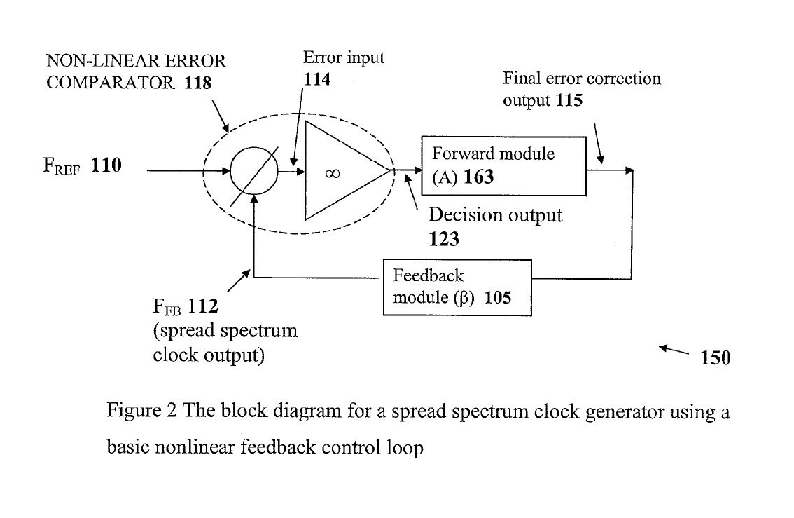

A nonlinear feedback control loop 150 as shown in FIG. 2 becomes a spread spectrum clock generator since the nonlinear error comparator 118 inevitably produces incorrect decisions due to the inherent loop delay; when the nonlinear error comparator 118 produces as many correct decisions as the incorrect decisions, the nonlinear feedback control loop 150 will oscillate and the oscillation of the loop is modulated by the random noise around the decision threshold of the nonlinear error comparator 118 since a small noise perturbation around the decision threshold can change the outcomes of the nonlinear error comparator 118.

Once the nonlinear error comparator 118 produces an output, the output will remain at the same state until a new output state is produced at the end of next comparison cycle. As a result, the nonlinear error comparator 118 can only produce a digital H or L output state for the final error correction output 115 regardless of how small the error input signal 114 is. The transfer function of the final error correction output 115 vs. the error input signal 114 thus becomes digital and has only two stable digital output states and the output state of the final error correction output 115 is determined only by the polarity of the error input signal 114. Since the open-loop gain of the feedback control loop is equal to the derivative of final error correction output 115 vs. the derivative of error input signal 114, the effective open loop gain of the nonlinear feedback control loop 150 is an impulse function with infinite gain located at the point when the error input 114 is zero. In practice, the open loop gain of the nonlinear feedback control loop 150 will not be exactly an impulse function but will spread out slightly due to the intrinsic noise. Since the open loop gain of a feedback control loop must be greater than zero, the feedback signal F_{FB} 112 of the nonlinear feedback control loop 150 will thus always fluctuate randomly around the reference input signal F_{REF} 110.

The principle of using a nonlinear feedback control loop 150 as a spread spectrum generator can be proved by solving the feedback signal from the following equation,

$${V}_{FB} = {V}_{REF} * \frac{β A}{1 + β A} \qquad equ . 1$$

In equation 1, when the closed-loop gain (βA) is equal to infinity, the feedback signal 112 will be equal to the reference signal 110 regardless of the polarity of the open-loop gain (A). Since there are two different solutions, positive A and negative A, to satisfy a first-order equation; these solutions are unstable and the system will oscillate between positive open-loop gain A and negative open-loop gain A since both gains produce the same result.

In the traditional theory of feedback control loop, a feedback control loop can oscillate only when βA=−1 since a feedback output signal can be produced without a reference input under this condition. The condition of βA=−1, however, is very strict since the phase of the closed-loop gain must be equal to 180 degree precisely and the amplitude of the closed-loop gain must be equal to 1 precisely at the same time to satisfy the oscillation condition. When an oscillator is operated under the condition of βA=−1, the oscillation output from the oscillator is narrowband because it is very difficult if not impossible to satisfy βA=−1 over a large bandwidth and the reference input signal 110 is not needed to produce an oscillation output signal. In contrast, when the nonlinear feedback control loop oscillates under the condition βA=∞, the oscillation is wideband since it can occur over a large bandwidth easily. Additionally, a wideband oscillation from a nonlinear feedback control loop 150 can not be sustained and the loop will be pushed to and stuck at the power supply rail if the reference input signal 110 is absent.

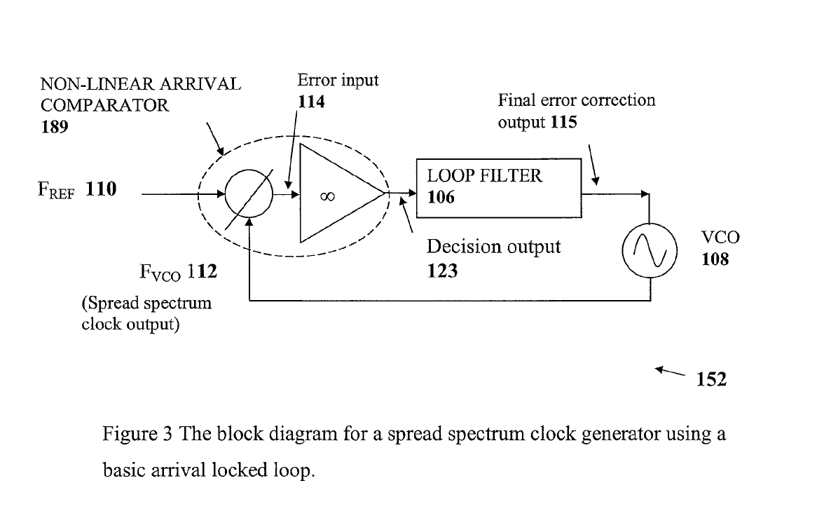

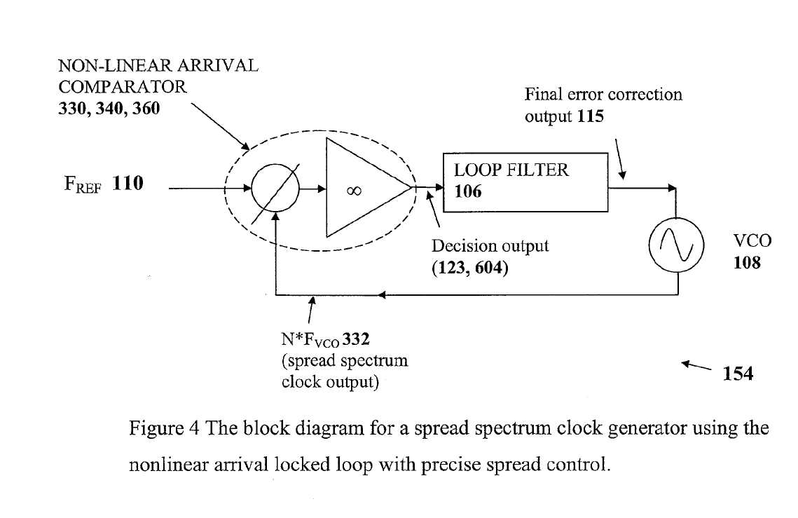

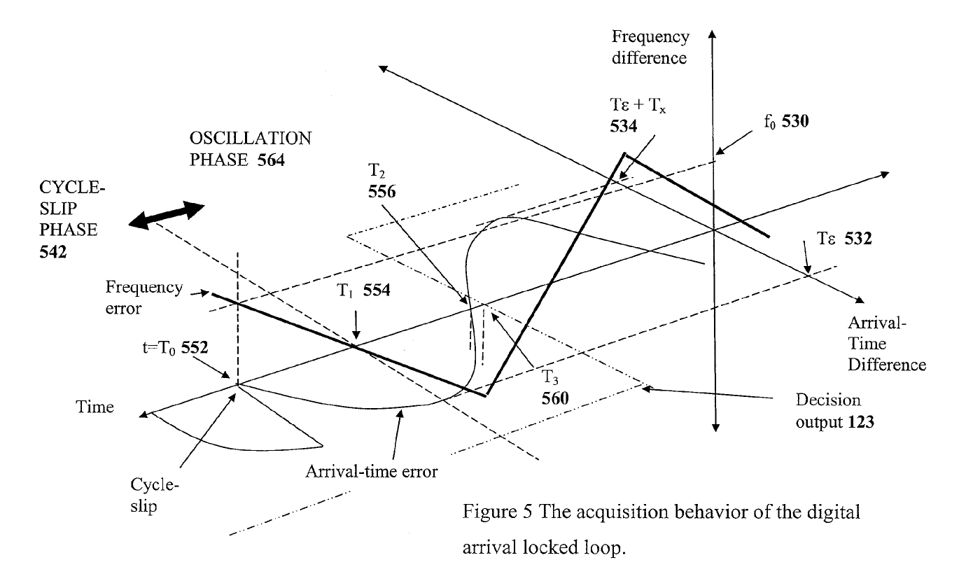

The process to generate spread spectrum clock signal from a basic nonlinear arrival locked loop 152 using an accurate arrival comparator 189 as shown in FIG. 3 or from an improved nonlinear arrival locked loop 154 using an accurate arrival comparator with precise frequency spread control 330 as shown in FIG. 4 can be explained in FIG. 5. In the FIG. 5, assuming that the frequency of the feedback signal 112 from VCO is far below the frequency of reference signal 110 initially and the arrival comparator (189, 330) is pumping up the frequency of feedback signal 112, the frequency of feedback signal 112 will be eventually equal to the frequency of the reference signal 110 occurring at T₁ 554. Assuming that the last arrival synchronization occurred at T₀ 552 before the frequency synchronization occurs at T₁ 554; since the frequency error f₀ 530 at T₀ 552 is assumed to be positive, the frequency of feedback signal 112 is slower than the frequency of reference signal 110 all the time between T₀ 552 and T₁ 554. The arrival of feedback signal 112 will thus continue to fall behind the arrival of reference signal 110 further and further after the last arrival synchronization occurred at T₀ 552 and the lagging of feedback signal 112 reaches the maximum at T₁ 554.

After the frequency synchronization point of T₁ 554, due to the large difference in arrival-time, the arrival comparator (189, 330) will continue to pump up the frequency of the feedback signal 112 so that the frequency difference will become negative and the feedback signal 112 will become the faster signal after T₁ 554. With a faster frequency, the arrival of feedback signal 112 will now be advancing to catch up with the arrival of reference signal 110. The advancing of feedback signal 112 will finally be stopped and the polarity of the decision output signal 123 from arrival comparator (189, 330) will be reversed at T₃ 560 shortly after the arrival synchronization occurs at T₂ 556 again. The time T₃ 560 always occurs later than T₂ 556 due to the positive random latency delay time of the accurate arrival comparator (189, 330). As a result, although the frequency difference becomes negative after T₁ 554, the arrival comparator (189, 330) will not flip its decision 123 to pump down the frequency of feedback signal 112 immediately due to the large arrival-time error at the time T₁ 554. The arrival comparator (189, 330) is finally about to flip its decision 123 when the arrival-time error is completely corrected and finally become zero at the time T₂ 556. But due to the random positive latency delay time from the uncertainty window of decision threshold of the accurate arrival comparator (189, 330), the decision output signal 123 from arrival comparator (189, 330) will be finally flipped some time later at T₃ 560 and the frequency of the feedback signal 112 reaches the top of frequency spread at the same time. After the arrival comparator (189, 330) flipping the polarity of the its output signal 123 at T₃ 560, a new cycle into the opposite direction begins and the frequency of feedback signal 112 will always be either pumped up or pumped down and will bounce between the arrival synchronization points constantly and the nonlinear arrival locked loop (152, 154) oscillates forever.

The period of the frequency spread of feedback signal 112 between the two arrival synchronization points T₀ 552 and T₂ 556 totally depends upon the amount of arrival-time difference at the frequency synchronization point T₁ 554 which can range from 0 to the period of the reference signal 110. Randomizing the arrival-time difference at the frequency synchronization point T₁ 554 will thus randomize the frequency spread of the spread spectrum clock signal. One way to randomize the arrival-time difference at the frequency synchronization point T₁ 554 is to increase the arrival-time difference in a small random amount cycle after cycle for every cycle of the frequency spread until the period of frequency spread becomes so long that cycle-slip occurs to reset both the period of frequency spread and the amount of arrival-time difference to a small amount near 0. The arrival-time difference between the feedback signal 112 and reference input signal 110 in each cycle of frequency spread is always at its peak when the frequency difference is zero which always occurs at approximately half way between any two subsequent arrival synchronization points. The arrival-time difference between the feedback signal 112 and the reference input signal 110, nevertheless, can't be longer than the period of the reference input signal 110 since a cycle-slip would have occurred to reset the arrival-time difference. As a result, cycle-slip always occurs when the frequency difference is near zero.

An accurate arrival comparator (189, 330) can produce the needed increase of arrival-time difference for the frequency spread of arrival locked loop (152, 154) since an accurate arrival comparator (189, 330) will change its output state 123 only after the polarity of its error input signal 114 has changed the state but never before. The change of state at the output 123 of an accurate arrival comparator (189, 330) will always occur later than the change of state at the input 114 of the accurate arrival comparator (189, 330) by a small and random amount of time depending upon the size of the uncertainty window around the decision threshold of the accurate arrival comparator (189, 330). As shown in the FIG. 5, since the arrival of feedback signal 112 is falling behind all the time between T₀ 552 and T₁ 554, it will take the same amount of time from T₁ 554 to T₂ 556 for the arrival locked loop (152, 154) to advance the arrival of feedback signal 112 to reach the arrival synchronization point again since the feedback signal 112 is slewing at the constant rate during the entire time between T₀ 552 and T₂ 556. Nevertheless, the arrival comparator (189, 330) will not flip its output 123 until a short time after T₂ 556 later at T₃ 560 since the feedback signal 112 must cross over the decision threshold to cause the accurate arrival comparator (189, 330) to flip its output 123. Using an accurate arrival comparator (189, 330) can thus guarantee that the output 123 of the accurate arrival comparator (189, 330) will remain at the current state for a period slightly longer than actually required by the input 114. As a result, the time period between T₁ 554 and T₃ 560 will be slightly longer than the time period between T₀ 552 and T₁ 554 by a small and random amount of time.

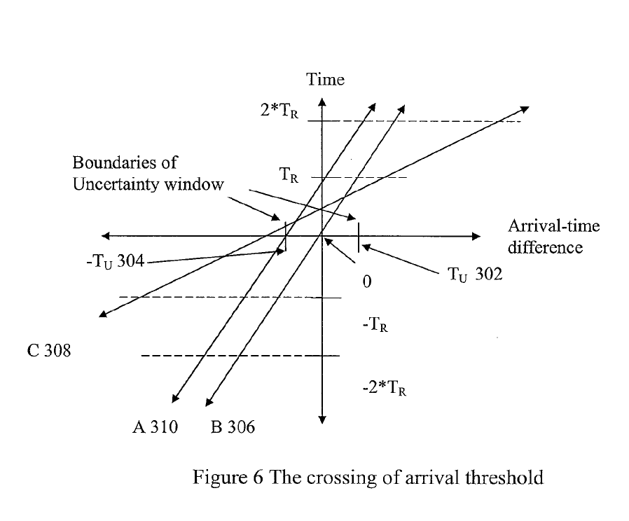

FIG. 6 shows an enlarged illustration of how the arrival of feedback signal 112 crosses over the decision threshold. The horizontal axial of FIG. 6 is the arrival-time difference and the vertical axial is the arrival-time of reference signal 110 which arrives at a fixed rate and the three slanted lines representing the three possible arrival comparisons before and after the arrival of feedback signal 112 crossing over the arrival of reference signal 110.

The line A 310 represents the case when the arrival of feedback signal 112 occurs near at the negative end of the uncertainty window (−T_{U} 304) of decision threshold when the arrival-time difference is about the change sign; the arrival-time differences of line A 310 are as follows—much larger than the negative window at t=−T_{R}, near negative edge of uncertainty window (−T_{U} 304) at t=0, within positive window (T_{U} 302) and near arrival synchronization at t=T_{R} and outside the positive window (T_{U} 302) at t=2*T_{R}. When the arrival of feedback signal 112 is crossing over the arrival of reference signal 110 according to line A 310, the feedback signal 112 will step inside the positive uncertainty window between 0 and T_{U} 302 once.

The line B 306 represents the case when the arrivals of feedback signal 112 occur at the same rate as line A 310 and the arrival of feedback signal 112 almost synchronizes with the arrival of reference signal 110. The arrival-time difference of line B 306 are as follows—just outside the negative window (−T_{U} 304) at t=−T_{R}, slightly negative and near arrival synchronization at t=0, near the edge of positive window (T_{U} 302) at t=T_{R} and outside the positive window (T_{U} 302) at t=2*T_{R}. When the arrival of feedback signal 112 is crossing over the arrival of reference signal 110 according to line B 306, the feedback signal 112 will also step inside the positive uncertainty window between 0 and T_{U} 302 once.

The line C 308 represents the case when the arrivals of feedback signal 112 occurs at a much faster rate than the previous two cases and the arrivals of feedback signal 112 skip the whole uncertainty window between −T_{U} 304 and T_{U} 302. When this happens, the outcomes of the arrival comparison become more predictable and the frequency spread becomes less random.

The feedback signal 112 has to visit the positive uncertainty window between 0 and T_{U} 302 at least once when the arrival-time difference between feedback signal 112 and reference input 110 signal is changing from negative to positive in order for the accurate arrival comparator (189, 330) to produce an unpredictable latency delay time due to the uncertainty window around the decision threshold—this is how the nonlinear arrival locked loop (152, 154) produces a spread spectrum clock output signal with random frequency modulation. Likewise, when the arrival-time difference between feedback signal 112 and reference input signal 110 is changing from positive to negative, the feedback signal 112 must visit the negative uncertainty window between 0 and −T_{U} 304 at least once for the accurate arrival comparator (189, 330) to produce an unpredictable latency delay time when the arrival of feedback signal 112 is crossing over the arrival synchronization point.

To guarantee that the feedback signal 112 will not skip the uncertainty window between −T_{U} 304 and T_{U} 302, the slew rate or acceleration (a) from the arrival locked loop (152, 154) must not push the feedback signal 112 more than half of the size of uncertainty window in an arrival comparison period as follows,

½*a*T_{R}²<(T_{U}/T_{R}) equ. 2

where T_{R} is the period of the arrival comparison cycle. Assuming that the charge pump output current from the arrival comparator is I in Amp and the capacitance of the loop filter is C in Farad and the tuning sensitivity of the VCO is K_{VCO} in Hz/Volt and the division of the clock divider is N, the closed-loop gain of the loop or the slew rate or acceleration of feedback signal (a) is equal to

a=I*K_{VCO}/(C*N) equ. 3

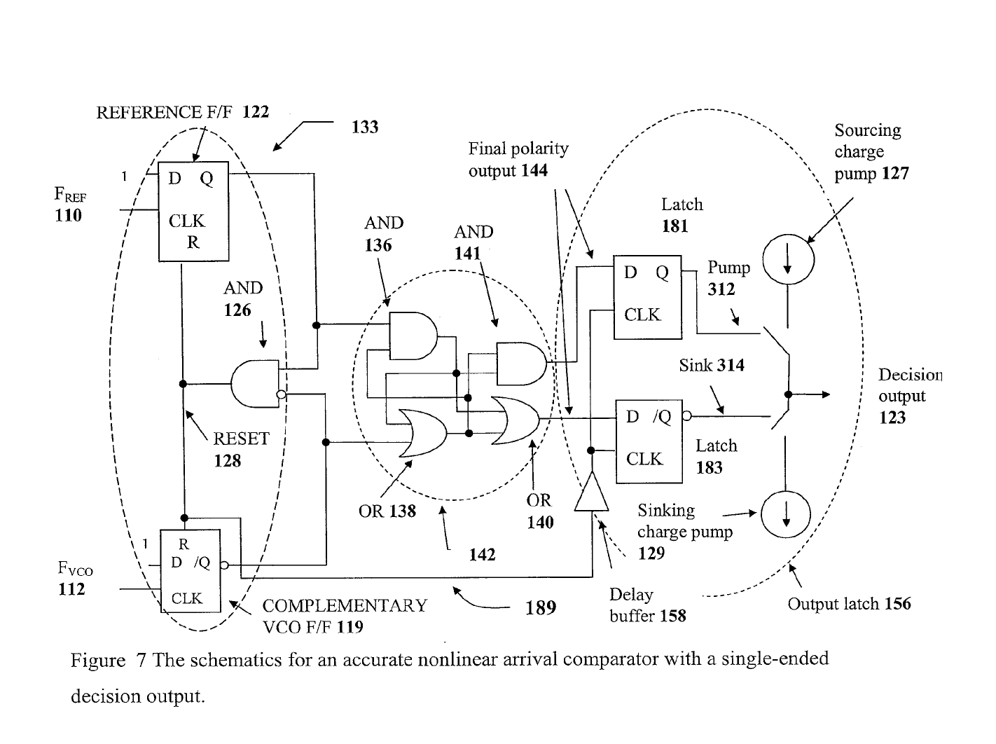

An accurate arrival comparator 189 as shown in FIG. 7 can produce a new decision 123 as soon as the late arrival signal arrives and an arrival comparison cycle is made of two arrival events, one from each of the two inputs. The accurate arrival comparator 189 is made of three modules, the PFD 133, the polarity selection circuit 142 and the output latches 156. The PFD 133, which is made of two flip-flops (122, 119) and an AND gate 126, produces two arrival signals for the polarity selection circuit 142 to select from; the arrival of reference signal 110 produces a positive arrival signal at the output of reference flip-flop 122 and the arrival of feedback signal 112 produces a negative arrival signal at the output of complementary VCO flip-flop 119. The polarity selection circuit 142 selects whichever polarity of arrival signal arrives first as the final polarity output signal 144 so that the final polarity output signal 144 is positive when the reference signal 110 arrives earlier and is negative when the feedback signal 112 arrives earlier. The final polarity output signals 144 are then stored into the output latches 156 as the pump 312 and sink 314 signals at the end of arrival comparison cycle to enable or disable the charge pumps to drive the loop filter 106 to produce the final error correction output 115.

Since the arrival of late arrival signal produces the reset signal 128 to clear the flip-flops of PFD 133 to end an arrival comparison cycle, the reset signal 128 can also be used as the trigger signal for the output latches 156 so that the decision output 123 of the arrival comparator 189 can only be updated when the current arrival comparison cycle is over.

The accurate arrival comparator 189 as shown in FIG. 7 is accurate due to the decision locking mechanism from the feedback arrangement of the polarity selection circuit 142. The polarity selection circuit 142 is made of two pairs of AND/OR logic gates; the first pair of AND 136/OR 138 logic gates with feedback allows the early arrival signal to block the late arrival signal from changing the state of final polarity output 144 once the output state of final polarity output 144 is asserted by the early arrival signal and the second pair of AND 141/OR 140 logic gates produces the final polarity decision outputs 144 from the outputs of the first pair AND 136/OR 138 logic gates. When the reference signal 110 arrives first, the output of AND 136 gate of the first pair of AND 136/OR 138 logic gates will become positive first which will produce a positive final polarity output 144 and prevent the OR gates of both the first and the second pair AND/OR logic gates from becoming negative. Likewise, when the feedback signal 112 arrives first, the output of OR 138 gate of the first pair AND 136/OR 138 logic gates will become negative first which will produce a negative final polarity output 144 and prevent the AND gate of both the first and second pair AND/OR logic gates from becoming positive. The output state of the final polarity output 144 will thus remain at the state determined by the first arrival signal until the end of arrival comparison cycle when both flip-flops of the PFD 133 are reset.

The feedback mechanism, unfortunately, produces bouncing decisions when the arrival-time difference between the two input signals is less than the propagation delay time of a single logic gate since it takes this amount of time to produce the feedback signal. If the late arrival signal arrives before the feedback signal is produced, the feedback signal will not be able to block the late arrival signal completely and bouncing decisions can be produced. The accurate arrival comparator 189 thus exhibits a decision uncertainty window of +/−(propagation delay of a single logic gate). Luckily, the bouncing decisions will not produce erroneous outputs for the accurate arrival comparator 189 due to the nature of AND 141 and OR 140 gate. When the reference signal 110 arrives earlier, the final polarity signal 144 at the AND 141 gate output of the second pair AND 141/OR 140 logic gates should become positive to eventually become a positive pump signal 312 to enable the sourcing charge pump 127 after the final polarity output 144 is latched; even if an incorrect negative output state is latched due to the bouncing decisions, since a negative output at the latched pump 312 output will not enable the sourcing charge pump 127, the bouncing decisions produce no erroneous output from the sourcing charge pump 127. During the entire time when bouncing decisions are produced at the AND 141 gate output of the second AND 141/OR 140 logic gates, the OR 140 gate output of the second pair AND 141/OR 140 logic gates remains positive constantly since an OR 140 gate can produce a positive output when either one of the inputs is positive so that the sinking charge pump 129 is completely disabled and producing no erroneous output, neither. Likewise, when the feedback signal 112 arrives earlier, the final polarity output signal 144 at the OR 140 gate output of the second pair AND 141/OR 140 gate should become negative to eventually becomes a positive sink signal 314 to enable the sinking charge pump 129 after the final polarity output 144 is latched; even if an incorrect positive output at the final polarity output 144 is latched due to the bouncing decisions; since a positive input at the latch becomes a negative sink signal 314 that will not enable the sinking charge pump 129, the bouncing decisions produce no erroneous output from the sinking charge pump 129. During the entire time when bouncing decisions are produced at the OR 140 gate output of the second pair AND 141/OR 140 logic gates, the AND 141 gate output of the second pair AND 141/OR 140 logic gates remains negative constantly since an AND gate produces a negative output when either one of the input signals is negative so that the sourcing charge pump 127 is completely disabled and produce no erroneous output, neither. As a result, an accurate arrival comparator 189 as shown in FIG. 7 can only produce either a correct output or no output at all but it will never produce an erroneous output with wrong polarity.

When the error input signal 114 of an accurate arrival comparator 189 as shown in FIG. 7 is slewing from the positive side into the negative side, the decision output 123 of the accurate arrival comparator 189 will thus never become negative as long as the error input signal 114 is still on the positive side. The decision output 123 of an accurate arrival comparator 189 might remain positive even after the error input signal 114 has moved into the negative side if the arrival-time difference is small and is within the decision uncertainty window and bouncing decisions are produced; nevertheless, the decision output 123 of the accurate arrival comparator 189 can become negative anytime. Once the decision output 123 of an accurate arrival comparator 189 is negative, the decision output 123 will remain negative indefinitely and will never become positive until the polarity of the error input signal 114 is changed again. The accurate arrival comparator 189 as shown in FIG. 7 can thus guarantee that the change of state at the decision output 123 of the accurate arrival comparator 189 will always occur later than the change of state at the error input 114 of the accurate arrival comparator 189.

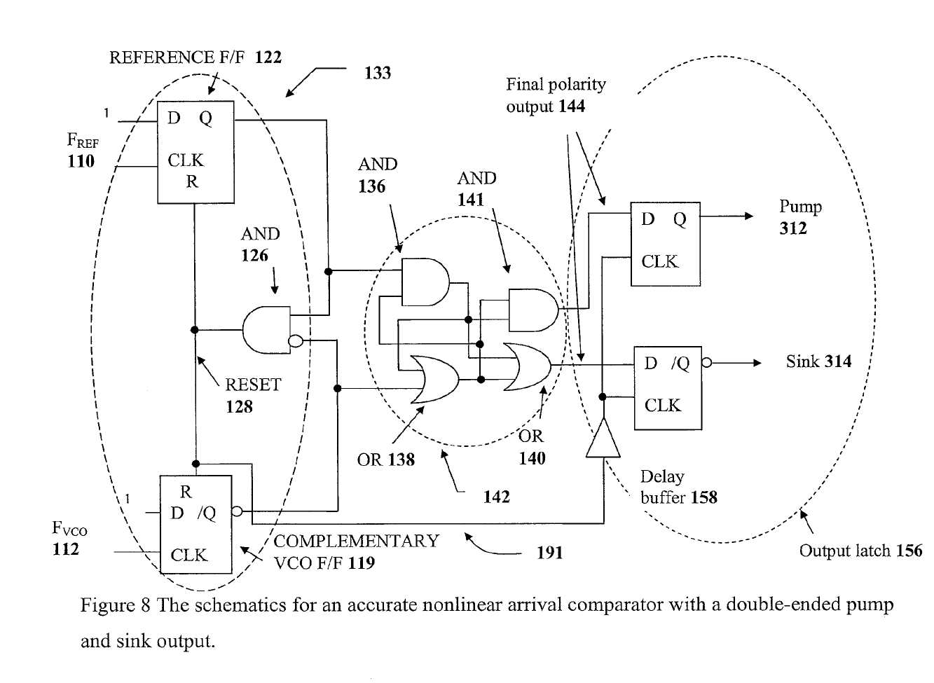

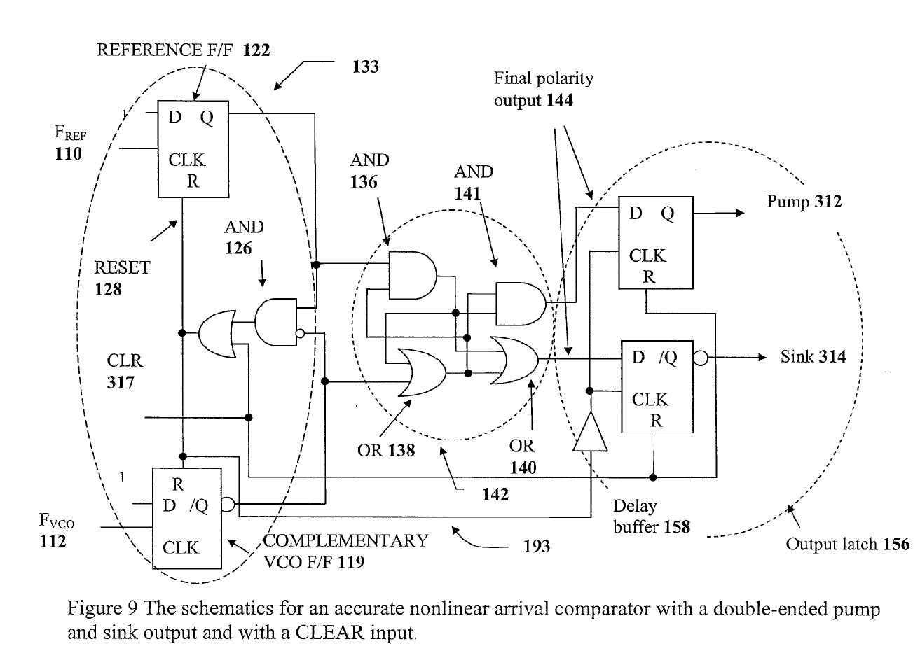

The single ended output of the accurate arrival comparator 189 can be simplified and replaced with a double-ended pump output 312 and sink output 314 as shown in FIG. 8. The arrival comparator with double-ended output 191 is simpler in design but it requires some means to convert the double-ended pump 312 and sink 314 output into a single-ended output eventually to become the final error correction output 115 for the VCO 108. A CLR 317 input can also be added to the arrival comparator with double-ended output as shown in FIG. 9 to return the arrival comparator 193 to the default state if needed.

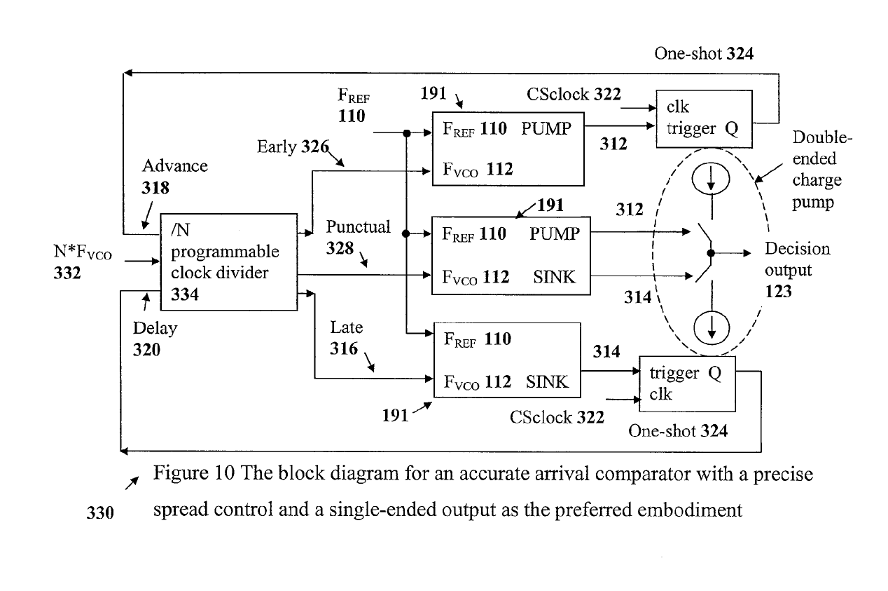

Since the cycle-slip will occur only when the arrival-time difference at the frequency synchronization point is longer than a period of reference signal 110, it can take a long time for the feedback signal 112 to travel to produce the cycle-slip and the period of the random frequency modulation signal can be very long. Unfortunately, a long period of modulation signal is undesirable for spread spectrum clock generator since the frequency of modulation signal can fall inside the audible range. One way to reduce the traveling time needed for feedback signal 112 to produce cycle-slip and to increase the frequency of random modulation signal is to use an early arrival comparator and a late arrival comparator to produce cycle-slips as shown in FIG. 10 so that the feedback signal 112, which should be called as the punctual signal 328 now, does not need to travel far to produce cycle-slips. In this design of accurate arrival comparator with precise spread control 330 as shown in FIG. 10, as soon as the reference signal 110 arrives earlier than the early signal 326, the early arrival comparator produces a pump signal 312 to trigger a one-shot generator 324 to produce a correction signal with duration equal to half of the clock period of one-shot generator 324 to advance the arrival of all three feedback signals produced from the VCO so that the next arrival of the punctual signal 328 will occur at the time when the early signal 326 would have arrived if there were no correction. Likewise, as soon as the reference signal 110 arrives later than the late signal 316, the late arrival comparator produces a sink signal 314 to trigger another one-shot generator 324 to produce a correction signal with duration equal to half of the clock period of the one-shot generator 324 to delay the arrival of all three feedback signals produced from the VCO so that the next arrival of punctual signal 328 will occur at the time when the late signal 316 would have arrived if there were no correction. All the three feedback signals, the early 326, punctual 328 and late 316 signals, are produced from the same high frequency clock signal 332 from VCO with a fixed phase offset by a state machine built with programmable clock divider 334 and all three feedback signals are compared with the same arrival from the reference input signal 110. The state machine clock divider 334 requires two control input signals, an advance input 318 and a delay input 320, to select the amount of clock division for the state machine. In the normal state of operation when both the advance input 318 and the delay input 320 are false, the state machine 334 simply increments its output state sequentially one by one; in the adjustment state of operation, the state machine 334 can either increment its output states by the amount of two when the advance input 318 is true or remain at the current state without incrementing when the delay input 320 is true. The arrival of clock signals produced from the state machine 334 of clock divider can thus be advanced or delayed by any amount of time in the multiple of the state machine's clock period as we desire. The clock signal for the state machine clock divider 334 can be called as a high frequency feedback clock 332.

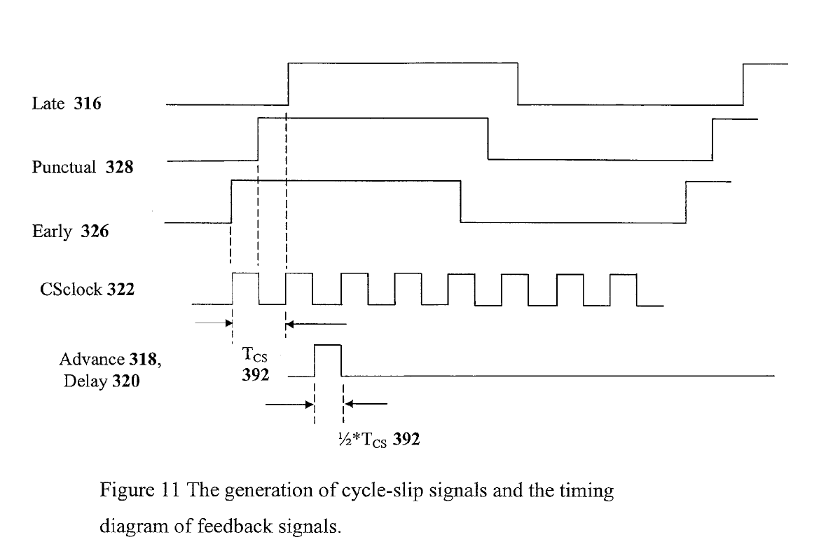

The arrival-time differences between the early signal 326 and punctual signal 328 and between the punctual signal 328 and late signal 316 are the same and these arrival-time differences are equal to either a period or a multiple periods of the state machine's clock signal 332 and are also equal to half of the period (T_{CS} 392) of the clock signal 322 for the one-shot generators 324 that produce the advance 318 and the delay 320 signals for the state machine clock divider 334 to produce cycle-slip. The timing diagram for the arrival of feedback signals of the accurate arrival comparator with precise spread control 330 and timing diagram of the cycle-slip clock 322 and output of one-shot 324 are illustrated in FIG. 11. The clock signal 322 of the one-shot generators 324 should ideally have 50% duty cycle. As a result, when the reference signal 110 arrives earlier than the early signal 326, the pump output 312 from the early arrival comparator will trigger the one-shot generator 324 to produce a pulse with duration equal to the arrival-time difference between the early signal 326 and the punctual signal 328 to advance the arrival of all feedback clock signals generated from state machine clock divider 334 by skipping the next state during the entire time when the advance input 318 from the output of one-shot generator 324 is true. Likewise, when the reference signal 110 arrives later than the late signal 316, the sink output 314 from the late arrival comparator will trigger another one-shot generator 324 to produce a pulse with duration equal to the arrival-time difference between the late signal 316 and the punctual signal 328 to force the state machine clock divider 334 to remain at the current state and to delay the arrival of all feedback signals generated from the state machine clock divider 334 during the entire time when the delay input 320 from output of one-shot generator 324 is true.

In the normal operation of the state machine clock divider 334 when both the advance input 318 and delay input 320 are false, the state machine clock divider 334 continues to increment the output state one-by-one sequentially until all states are visited once and the whole process repeats itself over and over again. For example, a divide-by-16 frequency divider can be used as the state machine clock divider 334 to produce 16 output states; the output state of the state machine clock divider 334 will run sequentially from state 1 to state 16 and back to state 1 to restart the whole process again once all the 16 output states have been visited once. The delay input 320 can hold the state machine clock divider 334 to remain at the current state so that the period of output signals from the state machine clock divider 334 will become longer when the delay input 320 is true. When the delay input 320 is true for a period of the high frequency clock input signal 332 to the state machine 334 clock divider, the arrival of the next output signal from the state machine clock divider 334 will occur at a clock period of high frequency clock input 332 later. On the other hand, the advance input 318 can force the state machine clock divider 334 to skip the next state so that the period of output signal from state machine clock divider 334 will become shorter when the advance input 318 is true. When the advance input 318 is true for a clock period of the high frequency clock input signal 332 to the state machine clock divider 334, the arrival of next output signal from the state machine clock divider 334 will arrive at a clock period of high frequency clock input 332 earlier.

For example, suppose a programmable divide-by-16 frequency divider clocked by the high frequency feedback signal 332 is used as the state machine clock divider 334 to produce the early 326, punctual 328 and late 316 signal to be compared with the arrival of reference input signal 110; the period of arrival comparison cycle will then be equal to 16 clock periods of the high frequency feedback signal 332 or equal to a period of reference input signal 110. Assuming the arrival-time difference between the early 326 and the punctual 328 signals is 1/16 of the period of reference signal 110 or is a cycle of high frequency clock signal 332, the period of the clock input signal 322 to the one-shot generator 324 will thus be ⅛ of the period of reference signal 110. Since the one-shot generator 324 can produce an output pulse with duration equal to half of the period of clock input signal 322, the one-shot generator 324 can thus produce a correction signal with duration equal to 1/16 of the arrival comparison clock cycle or a full cycle of high frequency feedback signal 332 for the state machine clock divider 334 so that the correction period to the state machine clock divider 334 is equal to arrival-time difference between the early 326 signal and the punctual 328 signal and between the punctual 328 and the late 316 signals. When the pump 312 output of the early arrival comparator becomes true, the state machine clock divider 334 will thus advance the arrival of all the output signals from the clock divider so that the next arrival of punctual signal 328 will arrive at the time when the early signal 326 would have arrived if the advance input 318 to the state machine clock divider 334 were not true. Likewise, when the sink output 314 of the late arrival comparator becomes true, the state machine clock divider 334 will delay the arrival of all the output signals from the state machine clock divider 334 so that the next arrival of punctual signal 328 will arrive at the time when the late signal 316 would have arrived if the delay input 320 to the state machine 334 clock driver were not true—cycle-slips are thus produced. With the cycle-slips produced by the early arrival comparator and late arrival comparator, the punctual signal 328 only needs to travel longer than the arrival-time difference between the early 326 and the punctual 328 signals or between the late 316 and the punctual 328 signals which can be a fraction of the period of the reference input signal 110, to trigger a cycle-slip. Since the arrival-time differences between the early signal 326 and the punctual signal 328 and between the punctual signal 328 and the late signal 316 determines the amount of frequency spread of the spread spectrum clock output, the amount of frequency spread on the spread spectrum clock output signal can be adjusted easily. The amount of frequency spread and the frequency of oscillation can be calculated as follows,

Assuming the maximum total time that the signal from VCO can ramp continuously before cycle-slip occurs is equal to Tₚ which is also equal to the time for the punctual signal 328 to ramp from the arrival synchronization point to the frequency synchronization point, the Tₚ is thus equal to

½*a*Tₚ²=M/N equ. 4

The left side of the above equation is the distance that the punctual signal 328 travels during the ramping period of Tₚ. The right side of the above equation is the ratio of the distance between the early signal 326 and the punctual signal 328 where M is the number of clock cycles of high frequency clock signal 332 that the early signal 326 is ahead of the punctual signal 328 to the distance of a cycle of reference input signal 110. From the above equation, we can calculate the peak-to-peak frequency spread Δf and the period of oscillation T_{OSC} as follows,

Δf=2*Tₚ*a equ. 5

T_{OSC}=4*Tₚ equ. 6

A one-shot generator 324 is a very well-known art that requires two input signals, a trigger input and a clock input 322, to produce a pulse output. Shortly after the trigger input becomes true and if the trigger input remains true for a period longer than two periods of the clock input signal 322, a stable output pulse is produced. The duration of the output pulse can be as short as half of the period of the clock input signal 322 since it can be produced from the non-triggering part of the clock input signal 322. The clock input signal 322 to the one-shot generators 324 can thus be called as the cycle-slip clock 322 (CSclock) since it determines how long to delay or to advance the output signal from the state machine clock divider 334 and cycle-slip clock signal 322 ideally should have 50% duty cycle in order to produce the advance 318 and delay 320 signal precisely and the cycle-slip clock should be produced from the high frequency feedback signal 332.

When the nonlinear arrival locked loop 154 using an accurate arrival comparator with precise spread control 330 is oscillating, the punctual arrival comparator will produce random linear frequency ramping modulation signals on the final error correction output 115 to modulate the frequency of VCO 108 and the duration of frequency spread becomes longer and longer cycle after cycle until the period of frequency spread is so long that cycle-slip is produced on the punctual signal 328 and the frequency spread is reset to a small amount close to zero. Ideally, the increase of the period of frequency spread should be random and small for every cycle of the linear frequency ramping so that every cycle of the linear frequency ramping becomes unpredictable and truly random and the cycle-slips are not produced very often since it can take many cycles of linear frequency ramping to grow the period of the frequency spread to be long enough to produce cycle-slip. However, since the increase of frequency spread in each cycle of low frequency modulation signal is determined by the random latency delay time of the accurate arrival comparator 191, the increase of frequency spread of the punctual signal 328 can be large if the punctual signal 328 travels a long distance during the random latency delay time period. Unfortunately, this happens to be the case for the arrival locked loop 154 since the frequency spread of the punctual signal 328 is always at its peak frequency when the arrival synchronization occurs and the punctual signal always travels a long distance during the random latency delay period. As a result, the increase of frequency spread of the punctual signal 328 is always large. Consequently, the top of the frequency spread will be reached very often and the frequency spread of the spread spectrum clock generated from an arrival locked loop 154 will not be perfectly random.

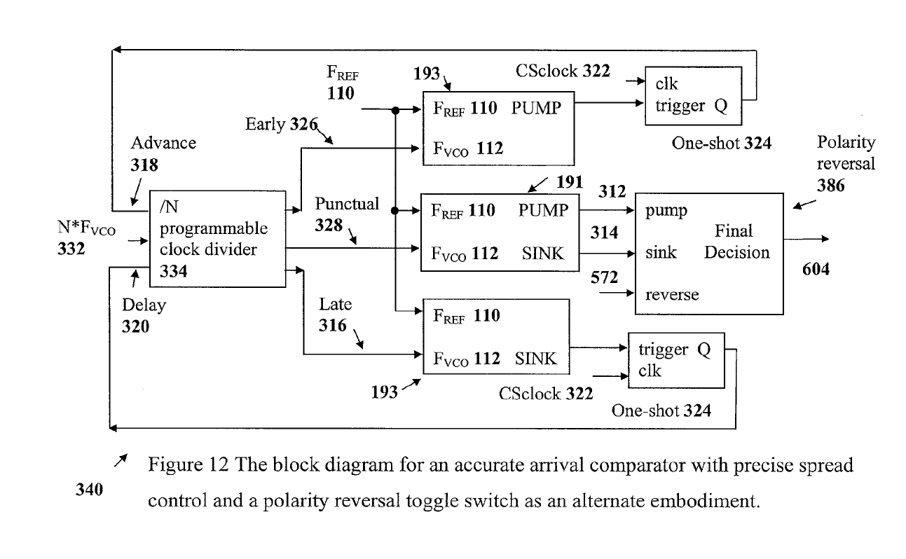

The best solution to improve the randomness of the frequency spread generated from an arrival locked loop 154 is thus simply to reduce the size of decision uncertainty window. Since the size of decision uncertainty window is determined by the amount of propagation delay time and an advanced manufacturing process for the circuits is required; unfortunately, this solution is not always practical. The other alternative solution to improve the randomness of frequency spread generated from an arrival locked loop 154 is to randomly toggle the polarity of the decision output signal from the arrival comparator 191 as shown in FIG. 12.

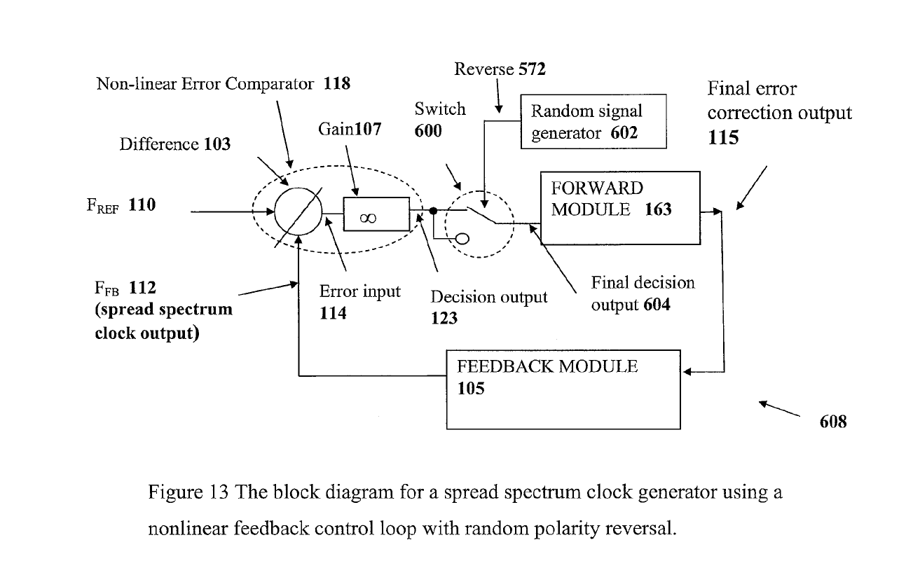

Since the nonlinear feedback control loop 150 produces correct and incorrect outputs for equally half of the time when the nonlinear feedback control loop 150 is oscillating, the polarity of the decision output signal 123 from nonlinear error comparator 118 can be reversed when the nonlinear feedback control loop 150 is oscillating. It is thus possible to use a toggle switch 600 controlled by a random signal generator 602 to randomly flip the polarity of the decision output signal 123 of the nonlinear error comparator 118 to further randomize the spread spectrum clock output 112 from the nonlinear feedback control loop as shown in the block diagram 608 as illustrated in FIG. 13.

A random signal generator 602 is a circuit that produces a random signal. A typical method to implement the random signal generator using digital circuit is to use the maximum length sequence technique by using a feedback loop with a number of flip-flops. In theory, if the number of flip-flop is N, the maximum number of output states can be generated from the maximum length sequence generator is 2^{N}−1 and the output signal from the maximum length sequence generator has 2^{N}−1 states before repeating itself. When the number of N becomes large, the output signal from the maximum length sequence generator thus becomes nearly random. The maximum length sequence generator is very popular in spread spectrum communication applications. In this application each data bit is spread by the random signal generated from the maximum length sequence generator to become 2^{N}−1 random chips so that a digital random signal generator is usually called a random chip generator. Regardless of how it is called, a random signal generator or a random chip generator is simply a device to produce a random output signal.

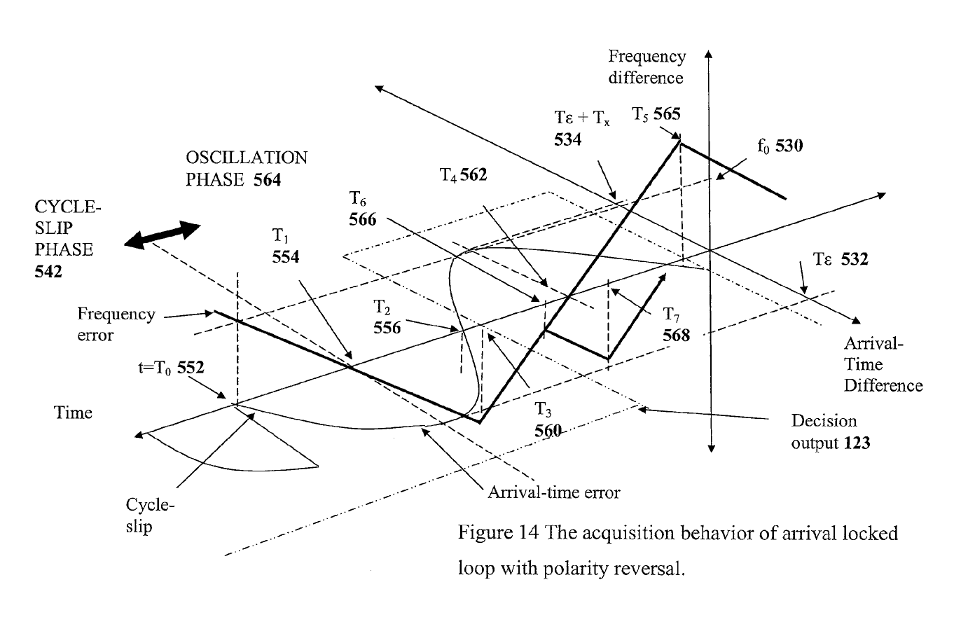

However, if we implement the technique of random polarity toggling as shown in FIG. 13 for the arrival locked loops (152,154); since the arrival locked loops (152,154) have memory which is the arrival-time difference when the polarity reversal occurs, toggling the polarity for the decision output 123 signal from an accurate arrival comparator (189, 330) randomly without toggling the polarity of memory can produce large frequency spread since the arrival locked loop (152, 154) will not be able to flip the direction of frequency spread again until after cycle-slip is produced. Unfortunately it will take a very long time for the cycle-slip to arrive after a polarity reversal has occurred since the arrival of feedback signal 112 is heading into a wrong direction after the polarity reversal so that the frequency spread of the spread spectrum clock output can become very undesirably large. For example, a typical frequency spread cycle is as illustrated in FIG. 14 which is a continuation of the FIG. 5 after the time T₃ 560; suppose the punctual arrival comparator reverses the polarity of its decision output signal 123 to become negative at time of T₃ 560 and a new cycle of frequency spread begins. Assuming that there is no polarity reversal to occur in this current frequency ramping cycle after t=T₃ 560; since the frequency of the feedback signal 112 is faster after T₃ 560, the arrival of the feedback signal 112 will arrive earlier than the arrival of reference signal 110 so that the decision output 123 of arrival comparator (189, 330) is negative to slow down the arrival of feedback signal 112. The arrival of feedback signal 112 will start to slow down due to the negative correction from arrival comparator (189, 330) but the arrival of feedback signal 112 is still earlier than the arrival of reference signal 110 since the frequency of feedback signal 112 is still much higher so that the arrival-time difference will continue to grow more negative after T₃ 560. The arrival-time difference will reach the maximum when the frequency error is finally becomes zero occurring at time T₄ 562 but the polarity of the output from arrival comparator (189, 330) will not be reversed until T₅ 565 after an arrival-time synchronization has finally occurred. The time period between T₃ 560 and T₄ 562 is slightly shorter than the time period between T₄ 562 and T₅ 565 due to the random positive latency delay time of the accurate arrival comparator (189, 330). If a polarity reversal occurs at T₆ 566 before the time of T₄ 562; since the polarity of arrival-time error is still negative and the arrival of feedback signal 112 is ahead of the arrival of reference input signal 110 and the frequency of the feedback signal 112 is also still higher than the frequency of reference input signal 110, the reversal of polarity at T₆ 566 will cause the arrival of feedback signal 112 to continue to arrive even more ahead of the arrival of reference signal 110. Since there will not be any cycle-slip to reverse the direction of frequency spread anytime soon because the arrival of feedback signal 112 must now ramp almost a distance of a whole cycle of the feedback signal 112 to reach the arrival of reference signal 110 in previous comparison cycle to produce a cycle-slip to reverse the direction of ramping, a long frequency spread is inevitable.

The simplest solution to avoid the problem of long frequency spread due to random polarity reversal is to prevent the frequency spread of the feedback signal 112 from changing direction quickly so that a large time constant is needed for the loop filter 106 and the oscillation frequency of the loop must be low when the polarity of the decision output signal 123 from arrival comparator (189, 330) is toggled randomly without toggling the polarity of loop's memory at the same time. As explained earlier, unfortunately, a low frequency modulation signal is undesirable for a spread spectrum clock generator so that this solution is far from a perfect solution.

The best solution to avoid the large frequency spread problem is to toggle the polarity of the loop's memory at the same time when the polarity of the decision output 123 signal from arrival comparator (189, 330) is toggled. As in the previous example, if we toggle the polarity of loop's memory so that the memory become positive after the polarity of the decision output from arrival comparator (189, 330) is reversed at T₆ 566; the arrival of feedback signal 112 is now behind the arrival of reference input signal 110 after the polarity reversal. As a result, since the arrival of feedback signal 112 is advancing after the polarity reversal has occurred at T₆ 566, a new arrival-time synchronization can occur very soon at T₇ 568 and a long frequency spread is avoided and the time period between T₃ 560 and T₆ 566 should be about the same as the time period between T₆ 566 and T₇ 568. The reversal of the polarity of decision output 123 from arrival comparator (189, 330) should thus only last for a short time and should only last for as long as the time period that the current cycle has traveled before the polarity reversal occurred. Based upon this principle, a state machine for polarity reversal must be operated under the following algorithm.

The state machine 386 for polarity reversal includes five modules:
1. count module 426 includes:
   A. a saturatable N bit Up/Down counter 384 clocked by a high frequency clock 390 has an U/D input 604, a hold input 428 and a reset input 430 and top count output 432, bottom count output 434, default count output 436, default count−1 output 438 and default count+1 output 440;
   B. an OR gate 442 produces the hold 428 input from two AND gates 444 and 446. The AND gate 444 becomes true when both final polarity output 604 and top count output 432 are true. The AND gate 446 becomes true when the bottom count 434 is true but the final polarity output 604 is false.
2. Up/Down module 420 includes:
   A. an Up/Down flip-flop 374 clocked by a high frequency clock 390 has an enable input and set and reset inputs and an Up/Down decision output 123 to store the current state of the Up/Down decision output from the arrival comparator 191;
   B. an AND gate 448 produces the set input for the Up/Down flip-flop 374 and the output of AND gate 448 becomes true when the pump 312 output signal of the arrival comparator 191 is true and the decision output 123 from the Up/Down flip-flop 374 is false;
   C. and an AND gate 450 produces the reset input for the Up/Down flip-flop 374 and the output of the AND gate 450 becomes true when both the sink 314 output signal of the arrival comparator 191 and the decision output 123 from the Up/Down flip-flop 374 are true.
3. toggle module 424 includes:
   A. a Toggle flip-flop 382 clocked by a high frequency clock 390 with an enable input and set and reset inputs produces a toggle control 454 output signal for polarity reversal toggle switch 600;
   B. an AND gate 456 produces the set input signal for the toggle flip-flop 382 and the output of AND gate 456 becomes true when the reverse input 572 is true while the toggle control output 454 and default count output 436 from the count 426 module are both false;
   C. an OR gate 458 combines the output from two AND gates 460 and 462 to produce the reset input signal for the toggle flip-flop 382. The AND gate 460 becomes true when the default count +1 440 from the count module 426 is true but the final polarity output 604 is false and the AND gate 462 becomes true when both the default count −1 438 and the final polarity output 604 are true.
4. reset module 422 includes:
   A. a reset flip-flop 380 clocked by a high frequency clock 390 with an enable input and data input to generate the reset signal 430 for the Up/Down counter 384;
   B. an OR gate 464 to produce the data input for the reset flip-flop 380 by combining the change of state inputs to the Up/Down flip-flop 374.
5. and a polarity reversal switch 600 that is controlled by the toggle control 454 signal to accept either the normal output from the Up/Down decision 123 output or the reversed Up/Down decision 123 output from the Up/Down module 420 as the final polarity output 604.

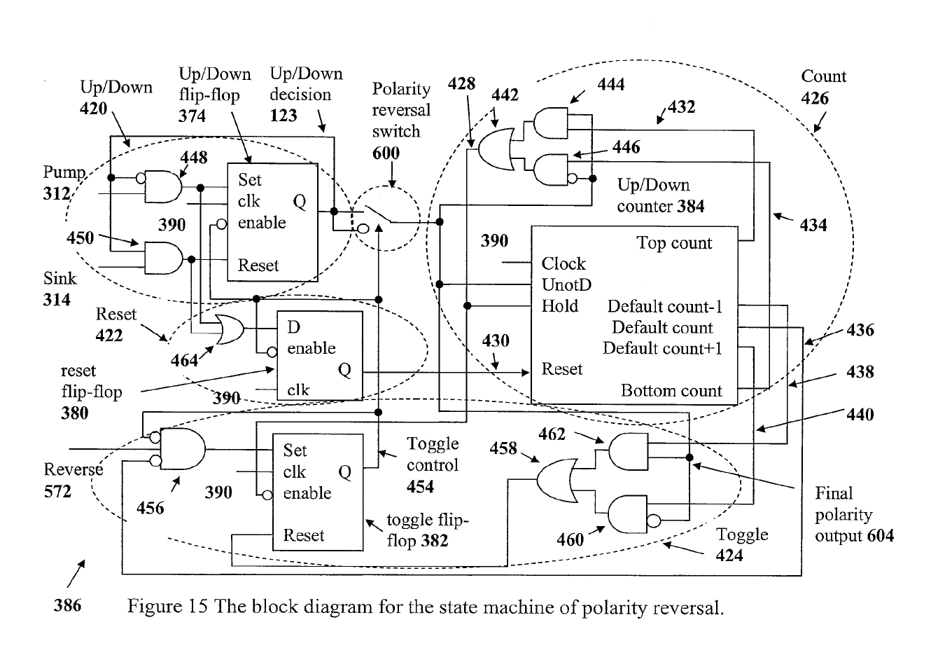

The state machine 386 of the polarity reversal can be implemented as shown in FIG. 15 that requires two inputs from the punctual arrival comparator 191, the pump 312 signal and the sink 314 signal and a separate reversal 572 input from a random signal generator 602 or any source that produces an output signal randomly. The two inputs signals from the punctual arrival comparator 191, pump 312 and sink 314, can be combined into one signal by using the decision output 123 of the arrival comparator as shown in FIG. 7, instead of the pump 312 and sink 314 signals; however, we will need two more current sources if we do so. The decision output 123 from the Up/Down flip-flop 374 is fed as the data inputs to a toggle switch 600 that selects either the normal decision output 123 or the reversed decision output from the Up/Down flip-flop 374 as the final polarity output 604 for the saturatable Nbit Up/Down counter 384 and also for the charge pump output drivers that drive the loop filter 106.

When the current state of the Up/Down flip-flop 374 is true (H) or UP, a true sink 314 signal from the punctual arrival comparator 191 will reset the Up/Down flip-flop 374 to false (L) or DOWN; when the current state of the Up/Down flip-flop 374 is false (L) or DOWN, a true pump 312 signal from the punctual arrival comparator 191 will set the Up/Down flip-flop 374 to true (H) or UP. The output of the Up/Down flip-flop 374 will remain at the current state for all other conditions.

When the current state of Up/Down flip-flop 374 is not equal to the next state of Up/Down flip-flop 374, the reset flip-flop 380 will become true to reset the saturatable Up/Down counter 384 to the default state 436. The default state (2^{N-1}) 436 of the saturatable Up/Down counter 384 is at half way between the top count 432 and bottom count 434 of the saturatable N bit Up/Down counter 384.

The toggle flip-flop 382 will be set when
1. the current state of toggle flip-flop 382 is not set and
2. the current state of the saturatable Up/Down counter 384 is not in the default state and is not saturated, neither and
3. the reverse input 572 is true.
   The toggle flip-flop 382 will be reset when
1. the current state of the saturatable Up/Down counter 384 is default count −1[(2^{N-1})−1] 438 and the Up/Down control 604 is true (UP) or
2. the current state of the saturatable Up/Down counter 384 is default count +1[(2^{N-1})+1] 440 and the Up/Down control 604 is false (DOWN)

The Up/Down flip-flop 374 and the reset flip-flop 380 and Toggle flip-flop 382 are not allowed to change the current state when the toggle flip-flop 382 is in the set state.

The N bit Up/Down counter 384 is a saturatable counter so that the N bit Up/Down counter 384 cannot overflow or underflow. When the state of the Up/Down counter 384 reaches the top count 432 and the Up/Down control 604 is true, the hold input 428 signal will become true so that the state of the Up/Down counter 384 will remain at the top count 432; when the state of the Up/Down counter 384 reaches the bottom count 434 and the Up/Down control 604 is false, hold input 428 signal will also become true so that the state of the Up/Down counter 384 will remain at the bottom count 434. Since the N bit Up/Down counter 384 is reset whenever the punctual arrival comparator 191 makes a new decision to reverse the direction of frequency spread while the toggle flip-flop 382 is not in set state, the N bit Up/Down counter 384 retains the memory for the traveling time of the current cycle of frequency ramping before the polarity reversal input becomes true.

When the punctual arrival comparator 191 produces an output to reverse the direction of frequency spread and if the toggle flip-flop 382 is not in the set state, the Up/Down flip-flop 374 will change its output state 123 to the new state and the Up/Down counter 384 will be reset to the default state 436 immediately afterward. The Up/Down counter 384 will then either count up or count down according to the new decision output 123 of Up/Down flip-flop 374. The state of Up/Down counter 384 will continue to either count up or down until the reversal input 572 becomes true or the Up/Down counter 384 is eventually saturated or the punctual arrival comparator 191 produces a new output to reverse the direction of frequency spread again.

The Toggle flip-flop 382 will be set to flip the polarity of final polarity output 604 when the reversal input 572 becomes true while the Toggle flip-flop 382 is not already in the set state and the Up/Down counter 384 is not in the default state 436 and is not saturated. Once the Toggle flip-flop 382 becomes set, it will remain in the set state until the state of the Up/Down counter 384 returns to the default state 436. During the period when the Toggle flip-flop 382 is set, both the direction of Up/Down counter 384 and the polarity of the final polarity output 604 is reversed. The Up/Down counter 384 will need the same amount of time as the current cycle has lasted before the reversal input 572 becomes true to return the Up/Down counter 384 to the default state. As a result, the polarity reversal can only last as long as the current cycle has lasted before the reversal input 572 becomes true. With this algorithm, the polarity reversal controlled by a random signal source 602 will not produce a large frequency spread while still allow the frequency spread to become more random.

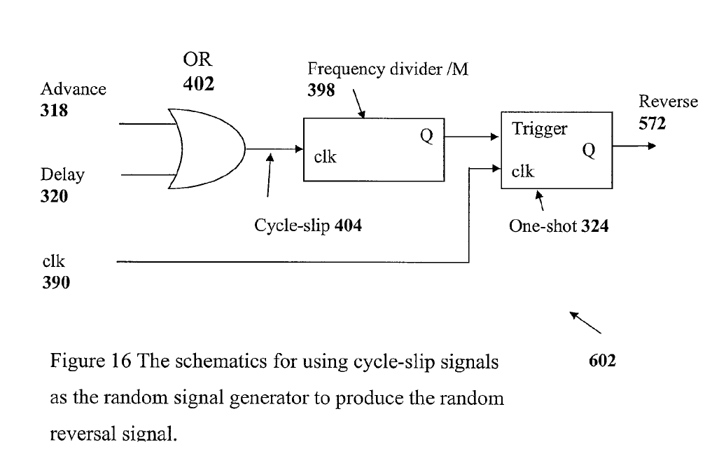

As shown in FIG. 14, since the arrival synchronization at T₂ 556 always occurs when the frequency spread of the punctual signal 328 is near its peak, the frequency ramping of the punctual signal 328 will always last longer than needed due to the random positive latency delay time of the accurate arrival comparator (330, 340) before the frequency ramping reverse the direction of slewing at T₃ 560. If the time period between T₁ 554 and T₂ 556 is equal to the arrival-time difference between the early signal 326 and the punctual signal 328, then the period between T₁ 554 and T₃ 560 and between T₃ and T₄ 562 must be longer than the arrival-time difference between the early signal 326 and punctual signal 328. As a result, after the polarity of frequency ramping is reversed at T₃ 560, cycle-slip will occur before the frequency spread of punctual signal 328 crossing over the clock's center frequency at T₄ 562 but never after since the time period between T₃ 560 and T₄ 562 is longer than the arrival-time difference between the punctual signal 328 and early signal 326. Since the generation of cycle-slip is determined by the random noise around the decision threshold, the generation of cycle-slip is random and the cycle-slip signals 404 can be used to toggle the polarity reversal switch 600 to randomize the frequency spread of clock even more. Using the cycle-slip signal 404 to toggle the polarity reversal switch 600 can thus save a significant amount of hardware needed for a random signal generator 602. Nevertheless, since the cycle-slip signal 404 always occurs before the frequency spread of the punctual signal 328 crossing over the clock's center frequency, the cycle-slip can prevent the punctual signal 328 from crossing over the clock's center frequency and limits the frequency spread of punctual signal 328 to only half of the total frequency spread if the cycle-slip signal 404 toggles the polarity reversal switch 600 constantly. As a result, the cycle-slip signal 404 must not toggle the polarity reversal switch 600 constantly and the fastest rate the cycle-slip signal 404 can toggle the polarity reversal switch 600 is alternatively or half of the rate of cycle-slip signal 404 so that the cycle-slip signal 404 must at least allow the frequency spread of the punctual signal 328 to pass through and to bounce off the clock's center frequency alternatively and the cycle-slip signal 404 may toggle the polarity reversal switch 600 at any rate lower than half of the rate of cycle-slip signal 404. FIG. 16 is the schematics for the generation of reverse signal 572 from the delay 320 and advance 318 inputs. In this design, the cycle-slip signal 404 is produced by combining the delay 320 and advance 318 inputs by using an OR gate 402 before being divided in frequency by a frequency divider 398. The division ratio M of the frequency divider 398 must be larger than 2. The divided cycle-slip signal then triggers a one-shot generator 324 to produce the reverse signal 572.

Using the cycle-slip signal 404 to flip the polarity of output signals from punctual arrival comparator 191 can save a significant amount of hardware needed for building a random signal generator 602; however, since the cycle-slip 404 can occur regularly to flip the polarity of output signals from punctual arrival comparator 191 at every other cycle of the frequency ramping spread, the cycle-slip signals 404 can produce undesired low frequency sub-harmonics of the modulation signal. The low frequency sub-harmonics of the modulation signal is less of a problem if the frequency of modulation signal is high so that the frequency of low frequency sub-harmonics of the frequency modulation signal is still above 30 Khz. The cycle-slip signal 404 should not be allowed to flip the polarity of the output signal of punctual arrival comparator 191 when the frequency of the modulation signal is close to 30 Khz. A frequency dependent restriction mechanism is thus required for the cycle-slip signals 404 to avoid the generation of sub-harmonics from the modulation signal. Since the saturatable Up/Down counter 384 retains the elapsed time of the current frequency ramping cycle, it can be used as a go-no-go gauge to determine whether if the frequency of the current frequency ramping cycle is too low and to activate the restriction mechanism to prevent the cycle-slip signal 404 from flipping the polarity of the output signals from the punctual arrival comparator 191. Since the count of the saturatable Up/Down counter 384 will be large if the period of frequency ramping cycle is long, we can thus determine whether if the frequency of the modulation signal is below a certain threshold by checking whether if the saturatable Up/Down counter 384 is saturated or not. If the saturatable Up/Down counter 384 is saturated, the current period of the frequency ramping cycle must be too long and the frequency of the modulation signal must be too low so that the cycle-slip signal 404 should not be allowed to flip the polarity of the decision output signal from the punctual arrival comparator 191. The maximum count of the Up/Down counter 384 thus determines the maximum period of the current ramping cycle that cycle-slip signal 404 is allowed to flip the polarity of the output signal from arrival comparator 191. With this algorithm, the hold input 428 to the Up/Down counter 384 can be also used as the disable signal for the Toggle flip-flop 382 so that the toggling of polarity of the output signal from punctual arrival comparator 191 is allowed only when the Up/Down counter 384 is not saturated and low frequency sub-harmonics are thus avoided.

Both the state machine of polarity reversal 386 and the random signal generator 602 should be clocked by a high frequency clock 390 with a frequency that is much higher than the frequency of the reference input signal 110 in order the reduce the latency delay due to Up/Down flip-flop 374.

Although using an accurate arrival comparator with precise spread control (330, 340) as illustrated in FIGS. 10 and 12 can produce a spread spectrum clock with a small and precise frequency spread; since the advance input 318 and the delay input 320 to the state machine clock divider 334 are in effect modulating the frequency of the spread spectrum clock signal 332, the arrival locked loop 154 can be trapped in one of the two saturation states when the frequency of the punctual 328 signal is moving too fast for the advance input 318 or delay input 320 to correct. This can become a problem during the power up since the frequencies of the reference input 110 and punctual signal 328 can move over a large range quickly. When the frequency of the punctual signal 328 is way above the frequency of reference input signal 110, the late arrival comparator will enable the sink output 314 to trigger the one-shot generator 324 to produce a correction output as the delay signal 320 to delay the arrival of punctual signal 328; at the same time, the sink output 314 from the punctual arrival comparator will also enable the sinking charge pump 129 to reduce the final error correction output voltage 115 to lower the frequency of the punctual signal 328. Both the late arrival comparator and the punctual arrival comparator can thus work together to quickly lower the frequency and to retard the arrival of the punctual signal 328. However, since the sink output 314 from the punctual arrival comparator can become false and the pump output 312 from the punctual arrival comparator can become true after the cycle-slip, the punctual arrival comparator can change the decision to pump up the frequency of punctual signal 328 after the cycle-slip and produce an erroneous correction for the frequency of punctual signal 328. If the erroneous correction on the frequency of punctual signal 328 is more than the correction of arrival from the delay input 320, the punctual signal 328 can be trapped and the arrival locked loop 154 will fail. The arrival locked loop 154 would never be trapped if the early and late arrival comparators were not used since the decision output 123 from punctual arrival comparator is always accurate and the arrival locked loop 154 by itself without the early and late arrival comparator has only a single stable operating point. However, at the presence of early and late arrival comparators, the punctual arrival comparator can produce erroneous decisions due to the cycle-slips produced from the early or late arrival comparators so that the arrival locked loop 154 can be trapped.

To solve the trapping problem, first, we need to detect the occurrence of trapping; once a trapping is detected, we simply need to disable whichever arrival comparator that produces the cycle-slip that caused the trapping momentarily until the arrival locked loop 154 is stably locked. Without the interferences of cycle-slips produced from the early or late arrival comparators, the punctual arrival locked loop 154 can quickly lock the arrival of punctual signal 328 to the arrival of reference input signal 110. Once the arrival of the punctual signal 328 is locked to the arrival of reference input signal 110, the early and later arrival comparators can then become active again to regulate the frequency spread for the spread spectrum clock output signal 332.

To detect the occurrence of trapping, we need to monitor the advance 318 and delay 320 signals from the one-shot generators 324. If the delay signal 320 generated by the late arrival comparator can not produce enough delay to slow down the frequency correction of punctual signal 328, the arrival locked loop 154 will be trapped; and the early arrival comparator will never have a chance to enable the pump output 312 to produce the advance signal 318. As a result, we can use a watchdog circuit 394 to detect the trapping due to the late arrival comparator by monitoring the advance input 318. If we use the advance input signal 318 as the reset input for the watchdog 394 and if the advance signal 318 is inactive for a certain long period, the arrival locked loop 154 must be trapped by the late arrival comparator so that the watchdog circuit 394 must produce an output signal to clear the late arrival comparator to disable the delay signal 320 and to remove the trapping. Once the advance signal 318 from the early arrival comparator occurs again, the watchdog 394 will immediately release the rest and the late arrival comparator will become active again to produce cycle-slip to regulate the frequency spread. Likewise, we need to monitor the delay input signal 320 and to connect the delay input signal 320 as the reset input to another watchdog circuit 394 to produce the clear signal for the early arrival comparator if the trapping occurs due to the early arrival comparator. With the two watchdogs 394 added to the arrival comparator 360, the arrival locked loop 154 will never be trapped.

In the normal state of operation of the arrival locked loop 154 when a normal spread spectrum clock output signal 332 is generated with a precise frequency spread; although the occurrence of each advance 318 and delay 320 signal is generated randomly, the generations of advance 318 and delay 320 signals occur at a certain constant rate over a fixed interval of time. However, if the arrival locked loop 154 is trapped in either one of the two trapped saturation states, either one of the advance 318 or delay 320 signals will be absent so that we can detect the occurrence of trapping by monitoring the occurrence of advance 318 and delay 320 signals.

The watchdog circuit 394 can be made of a simple ripple counter that has a reset input and clock input. A low frequency clock signal WDclock 396 can be used as the clock input signal for the watchdog 394 to save the amount of hardware needed for the ripple counter. If the reset input arrives regularly to the watchdog 394, the watchdog 394 will be reset to the default negative state regularly and will never have a chance to produce a positive output state to clear the arrival comparators but if the reset input to the watchdog 394 is absent for a period longer than the time it takes the watchdog 394 ripple counter to finally produce a positive output state, the watchdog 394 will produce a positive output signal to clear the arrival comparator and to remove the trapping. The positive output state from watchdog 394 will be reset immediately to the negative default output when the reset input signal to the watchdog 394 finally arrives again.

What is claimed is:

1. A system for producing a spread-spectrum clock signal using an arrival lock loop, said arrival lock loop comprising:
a non-linear arrival-time comparator having:
a first comparator input receiving a reference signal;
a second comparator input; and
a first comparator output;
a loop filter having:
a loop filter input coupled to said first comparator output; and
a loop comparator output; and
a voltage-controlled oscillator (VCO) having:
a VCO input coupled to said loop comparator output; and
a VCO output coupled to said second comparator input;
whereby said arrival lock loop produces a spread-spectrum clock signal having random frequency modulation and controllable variable frequency spread.

2. The system of claim 1, wherein said non-linear arrival-time comparator comprises:
a punctual arrival comparator generating a spread-spectrum output signal modulated with a random low-frequency modulation signal;
an early arrival comparator; and
a later arrival comparator;
said early arrival comparator and said late arrival comparator generating cycle-slips limiting the frequency spread of said spread-spectrum output signal.

3. The system of claim 2, further comprising:
means for generating a punctual signal having a punctual signal arrival time;
means for generating an early signal having an early signal arrival time;
wherein when said reference signal arrival time is ahead of said early signal arrival time, said early arrival comparator produces a pump signal that generates a correction signal to cause the next-occurring punctual signal to have punctual signal arrival time occurring at the time that the early signal would have arrived without correction.

4. The system of claim 3, further comprising:
means for generating a late signal having a late signal arrival time;
wherein when said reference signal arrival time is after said late signal arrival time, said late arrival comparator produces a pump signal that generates a correction signal to cause the next-occurring punctual signal to have punctual signal arrival time occurring at the time that the late signal would have arrived without correction.

5. A method of producing a spread spectrum clock signal using an arrival lock loop, comprising:
producing a spread-spectrum clock signal using said arrival lock loop, said spread-spectrum clock signal having random frequency modulation and controllable variable frequency spread.

6. The method of claim 5, further comprising:
generating a spread-spectrum output signal modulated with a random low-frequency modulation signal, using a punctual arrival comparator;
generating cycle-slips using an early arrival comparator and a late arrival comparator, wherein said cycle-slips limit the frequency spread of said spread-spectrum output signal.

7. The method of claim 6, further comprising:
generating a punctual signal having a punctual signal arrival time;
generating an early signal having an early signal arrival time;
wherein when said reference signal arrival time is ahead of said early signal arrival time, said early arrival comparator produces a pump signal that generates a correction signal to cause the next-occurring punctual signal to have punctual signal arrival time occurring at the time that the early signal would have arrived without correction.

8. The method of claim 7, further comprising:
generating a late signal having a late signal arrival time;
wherein when said reference signal arrival time is after said late signal arrival time, said late arrival comparator produces a pump signal that generates a correction signal to cause the next-occurring punctual signal to have punctual signal arrival time occurring at the time that the late signal would have arrived without correction.
